(19) United States
(12) Patent Application Publication
(10) Pub. No.: US 2015/0137088 A1
(43) Pub. Date: May 21, 2015

(54) RADIATION DETECTOR WITH AN ORGANIC PHOTODIODE

(71) Applicant: KONINKLIJKIE PHILIPS N.V., EINDHOVEN (NL)

(72) Inventors: Matthias Simon, Aachen (DE); Jorrit Jorritsma, Veldhoven (NL)

(73) Assignee: KONINKLIJKE PHILIPS N.V., EINDHOVEN (NL)

(21) Appl. No.: 14/402,729

(22) PCT Filed: Jun. 13, 2013
(86) PCT No.: PCT/IB2013/054845

§ 371 Date: Nov. 21, 2014

Related U.S. Application Data
(60) Provisional application No. 61/661,889, filed on Jun. 20, 2012.

(51) Int. Cl. H01L 27/30; H01L 51/44

(52) U.S. Cl. CPC H01L 27/308; H01L 51/44
USPC 257/40; 438/59

(57) ABSTRACT

The present invention relates to a radiation detector with organic photodiodes and to a method of producing such a radiation detector. The TFT backplane (103, 104) is placed between the scintillator (101) and the organic photodiode layer stack (105, 106, 107, 108). This implies the use of transparent TFT-electronics, e.g., a-Si with back-thinned glass or an organic TFT on foil. The geometrical order enables a multitude of possible stack built- ups for OPDs and has advantages for encapsulation and manufacturing.

### FIELD OF THE INVENTION

The present invention relates to a radiation detector for an examination apparatus, an examination apparatus comprising a radiation detector and a method of producing a radiation detector.

### BACKGROUND OF THE INVENTION

Flat digital x-ray detectors (FXDs) are usually built of a sensor plate, which comprises a matrix of detector elements, often referred to as pixel elements, with a photodiode and thin-film electronics for addressing and readout. The sensor plate of flat digital x-ray detectors may be made using amorphous silicon thin-film technology on glass, also called a-Si thin-film technology on glass. Usually a “passive pixel” technology is used, containing only a switch thin-film transistor (switch-TFT).

Amplification in this case may take place in charge sensitive amplifiers (CSAs) outside the sensor plate. If an “active pixel” technology is used, amplification is already done within the pixel.

X-rays are converted by a scintillator into visible light photons, which are subsequently detected by the photodiodes.

The scintillator may either be glued to the sensor plate or directly deposited on it. A known layer geometry in an x-ray detector from top, where the x-rays impinge, to bottom is scintillator-photodiode-thin-film transistor electronics on glass. The thin-film transistor electronics on glass may also be referred to as “backplane”.

### SUMMARY OF THE INVENTION

There may be a need to provide a different radiation detector geometry which enables the use of more common stack built-ups of the photodiode stack and which may also increase the number of possible photodiode stack-TFT backplane and CSA-type combinations.

This need may be solved by the subject-matter of the independent claims. Further embodiments are incorporated in the dependent claims or in the following description.

It should be noted that the following described aspects and embodiments of the invention apply both for the radiation detector as well as for the examination apparatus. Furthermore, features described in the following with respect to the radiation detector and/or the examination apparatus may also be implemented as method steps for producing the radiation detector and/or the examination apparatus. On the other side, method steps which are described in the following result in a radiation detector which is also part of the present invention.

According to a first aspect of the present invention, a radiation detector for an examination apparatus is provided, wherein the radiation detector comprises a scintillator, a thin-film transistor, which is part of a thin-film transistor layer, and a photoactive layer. The scintillator is adapted for receiving and absorbing incident radiation, such as, for example, x-rays or other forms of radiation, and for converting the incident radiation into light photons or incident high-energy photons into lower energy photons.

Furthermore, the thin-film transistor layer is arranged on a substrate, the substrate being arranged between the thin-film transistor layer and the scintillator. The photoactive layer is arranged at a side of the thin-film transistor layer facing away from the substrate.

In other words, the radiation detector according to an embodiment of the invention comprises a scintillator on top, followed by the substrate on which the thin-film transistor layer is arranged, which, in turn, is followed by a photoactive layer.

Of course there may be further elements or even layers arranged between the scintillator and the substrate, or between the thin-film transistor layer and the photoactive layer, such as electrodes, electron transport layers, hole transport layers and/or glue layers, for example.

The thin-film transistor layer, which is arranged on the side of the substrate which faces away from the scintillator, may have been prepared on the substrate, for example by depositing material onto the substrate followed by photolithography or printing techniques in order to structure the thin-film transistor backplane.

The thin film transistor is an element of the thin-film transistor layer. There may also be read-out and control lines included in that layer. The whole layer may also be denoted as ‘backplane’ which is used to read out the signals from the photoactive layer.

The radiation detector may comprise a plurality of detector elements, i.e. detector pixels.

The photons produced by the scintillator may typically have a wavelength which is bigger than the wavelength of the incident radiation. For example, the photons may be visible light photons or light photons with a wavelength above or below the visible spectrum, such as infrared light or ultraviolet light.

The photoactive layer may comprise an organic photodiode or a plurality of organic photodiodes and the thin-film transistor may also be an organic thin-film transistor.

According to an exemplary embodiment of the present invention, a cathode may be arranged at a side of the photoactive layer which faces away from the thin-film transistor layer. This cathode may comprise a structured or unstructured metal layer which serves as a mirror for photons emitted from the scintillator.

This mirror function may also be provided by a glass substrate arranged at the side of the photoactive layer which faces away from the thin-film transistor layer. For example, the surface of the glass substrate may be coated with a reflecting material, such as aluminium or another low work function material.

Low work function means, that electrons are quite easy to extract. In order to have a low dark current, it may be favourable in reverse biased diodes to have the positive contact with a low work function material, and the negative contact with a high work function material.

Alternative materials with low work function are Indium, Zinc and certain oxides.

According to another aspect of the present invention, an examination apparatus is provided which comprises the above and below described radiation detector.

In particular, the examination apparatus may be adapted as a medical x-ray imaging system. However, it may also be adapted in form of a baggage inspection system which may be used in an airport, for example.

According to another aspect of the present invention, a method of producing a radiation detector, and in particular one of the above and below described radiation detectors, is provided. The method comprises the steps of providing a substrate, depositing a thin-film transistor layer on the substrate and arranging a photodiode stack on the thin-film transistor layer.

For example, the photodiode stack is deposited on the thin-film transistor layer after the thin-film transistor layer has been deposited and structured, i.e. prepared, on the substrate.

In other words, first the thin-film transistor electronics is provided on a substrate and then the photodiode stack, which comprises the photoactive layer, is arranged on the thin-film transistor layer. Thus, the thin-film transistor layer is sandwiched between its substrate and the photodiode stack. “Arranging” the photodiode stack on the thin-film transistor layer may include deposition and lithography steps. Alternatively, the photodiode stack may be fabricated separately and then attached to the thin-film transistor layer. According to an aspect of the present invention, the geometrical order of photodiode stack and thin-film electronics backplane for a flat x-ray detector, i.e. the thin-film transistor layer together with its substrate, is reversed as compared to other detectors. More particularly, the thin-film transistor -backplane is placed between scintillator and photodiode layer stack. The photodiode layer may be an organic photodiode layer. This implies to use transparent TFT-electronics, e.g. a-Si with (a possibly back-thinned) glass or an organic TFT on foil. Possible TFT materials are a-Si and organic, amorphous metal oxides; transparent substrate materials are (thinned) glass or foil. In principle all combinations of TFT and substrate materials may be possible.

The reversed geometrical order enables more possible stack built-ups for organic photodiodes (OPDs) and has advantages for encapsulation and manufacturing.

These and other aspects of the invention will become apparent from and be elucidated with reference to the embodiments described hereinafter.

### BRIEF DESCRIPTION OF THE DRAWINGS

Exemplary embodiments of the invention will be described in the following with reference to the following drawings.

FIG. 1 shows a radiation detector according to an exemplary embodiment of the present invention.

FIG. 2 shows a radiation detector according to another exemplary embodiment of the present invention.

FIG. 3 shows a radiation detector according to another exemplary embodiment of the present invention.

FIG. 4 shows a radiation detector according to another exemplary embodiment of the present invention.

FIG. 5 shows a flow-chart of a method according to an exemplary embodiment of the present invention.

FIG. 6 shows a flow-chart of a method according to another exemplary embodiment of the present invention.

FIG. 7 shows an examination apparatus according to an exemplary embodiment of the present invention.

### DETAILED DESCRIPTION OF EMBODIMENTS

The illustration in the drawings is schematically and not to scale. In different drawings, similar or identical elements may be provided with the same reference numerals.

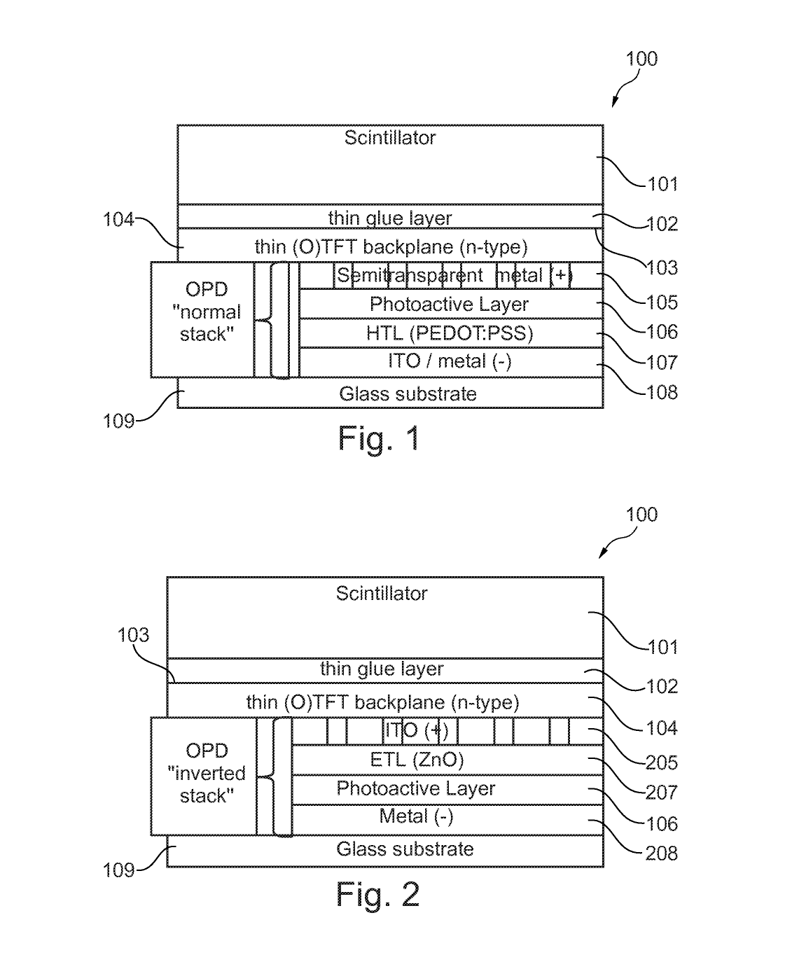

FIG. 1 shows a cross-sectional view of a radiation detector 100 according to an exemplary embodiment of the present invention.

Photodiodes as well as thin-film transistor electronics may be made of organic materials, e.g. polymers or small organic molecules like pentacene. Further, a combination of organic photodiodes (OPDs), organic thin-film transistors (OTFTs) and a scintillator can be used as x-ray detector. OPDs and OTFTs can be produced by various solution-based methods like printing, spraying or spin-coating, but also by lithographic processes.

In a passive pixel-type detector, the charge sensitive amplifiers can often handle only one type of charge carrier, either electrons or holes. In active pixel-type detectors also the type of transistors used in the pixel cell determine the polarity of charges that can be handled. Amorphous silicon circuits usually consist of n-type transistors collecting electrons from the photodiode, whereas organic TFT-circuits may be better in collecting holes (with p-type transistors).

OPDs have to be used under reverse bias conditions to ensure a low dark current, i.e., a low current through the device, when no light from the scintillator is present.

The reverse bias direction is determined by the order of different material layers in the OPD stack. The materials differ in the concentration of charge carriers of a certain type and the work function, enabling current to flow preferably only in one direction. The work function (WF) of the positively biased electrode is preferred to be lower than that of the negatively biased electrode.

If the photodiode is placed on top of the thin-film electronics, either the charge sensitive amplifiers type or the TFT-type of the backplane determines the layer geometry of the OPD stack together with the reverse bias condition.

The layer geometry of the OPD stack is in turn often not free to choose from a manufacturing point of view. Boundary conditions are:

1. a transparent OPD electrode in the direction of the scintillator;

2. only a thin transparent (carrier) layer between OPD and the scintillator to avoid light spread and scatter. The thickness of this layer should be well below the pixel size of the detector;

3. not all layers can easily be added on top of certain other layers, because of too high temperature loads during processing and/or not matching chemistry;

4. the charge collecting electrode has to be structured, i.e., the pixels have to be electrically isolated from one another.

The above-mentioned boundary conditions limit the number of manufacturing options for an OPD with optimal performance and may lead to an increased development effort.

An exemplary combination of TFT and OPD stack from bottom to top is: glass plate; TFT-ITO-pixel-anode (negative bias, high work function); hole transport layer (PEDOT:PSS); photoactive layer; top cathode (positive bias, low work function).

This stack cannot be used together with an electron collecting charge sensitive amplifier, because the reverse bias condition requires a negative anode polarity, whereas the electron collecting charge sensitive amplifier requires a positive bias at the anode.

One aspect of the invention is to reverse the geometrical order of thin-film readout electronics (“backplane”) and OPD. The light produced by the scintillator will in that case go through the thin-film readout electronics.

The thin-film readout electronics, i.e., the thin-film transistor layer, also called thin-film transistor backplane, is first provided on a substrate and then the OPD is either attached or deposited on the thin-film transistor layer.

The thin-film electronics (i.e. the thin-film transistor layer) may comprise or even consist of a) an organic TFT backplane produced on a very thin foil substrate having a thickness of 30 μm or even less, which is transparent for light, b) a thin or thinned version of a backplane made of s-Si or an organic amorphous metal oxide. Either the support glass is subsequently thinned to about 30 μm thickness (or less) or the a-Si TFTs are produced on foil, too. Light transparency has to be sufficient for using the thin-film electronics for a radiation detector according to the invention.

The reverse geometrical order may have the advantage of enabling the use of more common stack built-ups of OPDs and double the number of possible OPD stack-TFT backplane and CSA-type combinations. For example, the electrode facing away from the TFT backplane does not need to be light transparent. Hence, a metal layer, e.g., aluminium may be used, which also serves as mirror for light not absorbed in the organic photoactive layer. This may improve the external quantum efficiency and thus the image quality of the x-ray detector.

Another advantage may be that thicker glass plates below the OPD stack may be used because no light that carries image information may have to pass therethrough. These glass plates may not only be beneficial for handling during manufacturing, e.g., scintillator bonding, but may also may offer a robust encapsulation of the OPD stack to protect it against environmental conditions. The latter means that a light transparent thin-film encapsulation layer for protection of the OPD stack may no longer be required. This may not only save significant development effort but may also avoid possible additional restrictions to the OPD stack built-up and posed by the thin-film encapsulation layer.

OPD stacks which may be used in the radiation detector according to an aspect of the present invention may differ, depending on whether the transparent electrode (which consists of, for example, ITO material) is biased negatively or positively during operation of the detector. If the ITO-electrode is biased negatively, the opposite positive electrode may be a material with low work function, e.g., aluminium. This is also referred to as “normal” or “regular” stack OPD.

If the ITO is biased positively, the opposite negative electrode may consist of a higher work function material. This may be referred to as “inverted stack” OPD. Electrodes may not only consist of one material but may include a stack of different transparent oxide or metal layers.

Some options that are enabled by the reverse order geometry, i.e., TFT-backplane between scintillator and OPD are listed in the following. Different geometries, depending on the type of TFT backplane and/or the type of charge sensitive amplifier are distinguished. Basically, the distinction is between electron and hole collecting electronics, no matter whether an “active pixel” with a n/p-TFT-type or a “passive pixel” together with a certain CSA is used.

Common features of all embodiments may be a pixilated electrode of the OPD on the backplane side and a blanket (unstructured) electrode on the other side. Incident x-rays usually enter from the top, but in principle also a back-side illumination with x-rays may be possible, at least in some embodiments where the electrode on the other (i.e. the bottom) side is transmissive to x-rays.

Turning now back to FIG. 1, this figure shows a “normal” OPD stack geometry, according to which the scintillator 101 is followed by a thin glue layer 102 which attaches the scintillator 101 to the substrate 103 of the thin-film transistor layer 104. The thin substrate 103 and the thin-film transistor layer 104 are also referred to as “electron collecting electronics” and the thin-film transistor layer may be a thin, possibly organic, TFT backplane with n-type TFTs.

Below the electron collecting electronics 103, 104 a pixilated transparent or semi-transparent metal 105 which serves as cathode (+) is arranged, followed by a photoactive layer 106. After this photoactive layer, for example in the form of organic photodiodes, a hole transport layer 107 is arranged, i.e., PEDOT:PSS. Adjacent to and below the hole transparent layer (HTL) 107 an ITO and/or metal layer is arranged which is negatively biased (−) during operation of the detector, see reference numeral 108, whereas the semi-transparent metal layer 105 is positively biased (+) during operation of the detector.

Below the ITO/metal layer 108, a glass substrate 109 may be provided.

This glass substrate may improve the stability for the radiation detector 100 and may also provide for a mirror function to mirror the photons from the scintillator 101 back to the photoactive layer 106, thus increasing quantum efficiency of the radiation detector.

As may be seen from FIG. 1, the negative bias is applied to the bottom electrode 108, which may be a blanket of ITO or another high work function material, and a positive bias is applied on the structured transparent low work function material, i.e., the upper electrode 105.

FIG. 2 shows a radiation detector according to another exemplary embodiment of the present invention. The scintillator 101 is followed by an electron collecting electronics 102, followed by pixilated ITO (+) layer 205, which is positively biased during operation of the detector, followed by an electron transport layer (ETL, e.g. ZnO) 207, followed by a photoactive layer 106, followed by a metal acting as anode 208, which is negatively biased during operation of the detector, followed by a glass substrate 109, for example a glass plate.

The OPD stack is a so-called “inverted stack” with (during operation of the detector) a negative bias on the bottom metal layer 208 and a positive bias on the structured ITO pixel electrodes 205, which are arranged between the TFT backplane and the photoactive layer.

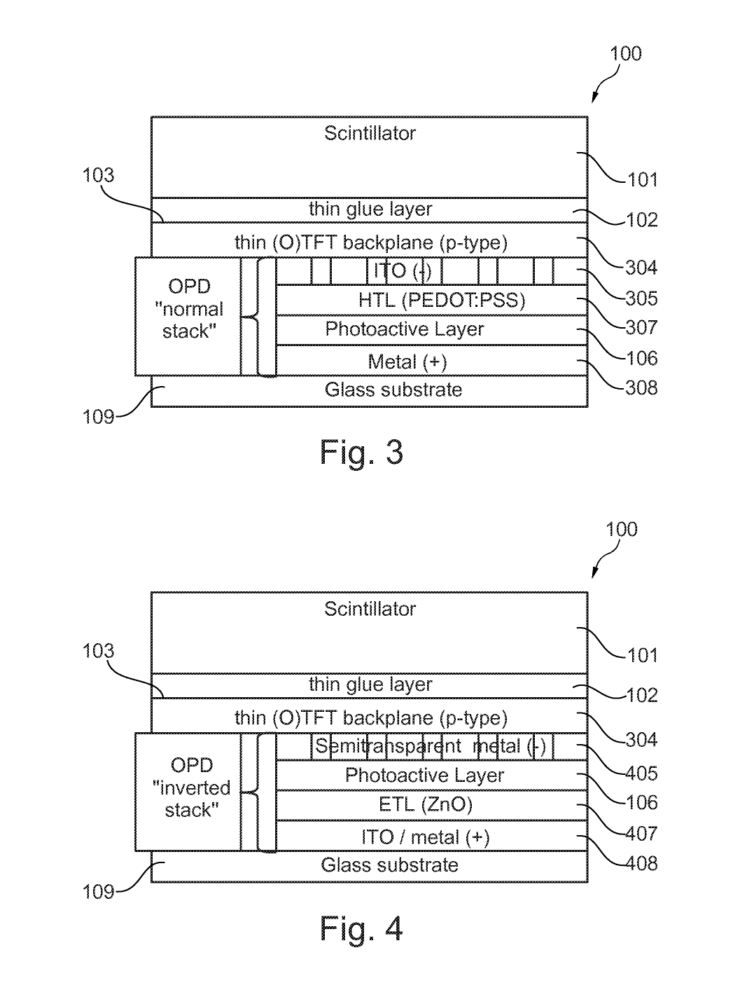

FIG. 3 shows a radiation detector according to another exemplary embodiment of the present invention. It should be noted that FIGS. 1 and 2 show embodiments with electron collecting electronics, whereas FIGS. 3 and 4 show embodiments with hole collecting electronics.

The stack is designed as follows: a scintillator 101 is provided which is followed by a thin glue layer 102, followed by a thin substrate 103 on which the TFT electronics 304 is arranged. The TFT layer may be an organic TFT layer and may be designed as hole collecting electronics (p-type). The hole collecting electronics 103, 304 is followed by a pixilated ITO (−) layer 305, which is followed by a hole transparent layer (for example PEDOT:PSS) 307, which in turn is followed by the photoactive layer 106. After the photoactive layer 106 a metal cathode with positive bias 308 during operation of the detector is arranged, followed by an optional glass substrate 109.

During operation of the detector the bottom metal layer 308 is positively biased and the structured ITO pixel electrodes 305 are negatively biased.

FIG. 4 shows a radiation detector according to another exemplary embodiment of the present invention, in which the scintillator 101 is followed by a thin glue layer 102, which is followed by a thin substrate 103 on which a p-type thin-film transistor backplane 304 is arranged (also called hole collecting electronics, which may be adapted as an organic TFT).

This is followed by a pixilated semi-transparent metal layer 405 acting as an anode and negatively biased during operation of the detector, which is followed by the photoactive layer 106, below which an electron transport layer, for example ZnO, 407 is arranged, followed by ITO or metal layer 406, which is positively biased during operation of the detector. A glass substrate 109 may be arranged below the lower electrode 408.

Once again, the lower, bottom electrode 408 is positively biased, whereas the upper, top electrode 405 is negatively biased during operation of the detector.

If the ITO electrode is biased positively (cathode in reverse bias) it can also be exchanged by a low work function metal, for example aluminium, especially in the case of the embodiment depicted in FIG. 4, as no light needs to pass through the bottom electrode. In this case, the aluminium also acts as a mirror to reflect light which has already passed through the OPD.

The pixilated, top electrode which faces the TFTs may already be part of the backplane electronics. In that case no additional conducting interconnection between the TFT backplane 304 and the pixilated electrode 405 may be necessary.

According to an example method of producing OPD for the radiation detector, first the ITO layer is provided because the quality of the layer may be better on a flat surface like glass or foil rather than on an already existing photoactive layer.

In other words, the ITO layer is deposited and structured on top of the thin-film transistor layer 304.

Hole and electron transport layers (ETL, HTL) are optional layers. OPDs may also be produced without them, just consisting of the photoactive layer and two electrodes, one on top and one below the photoactive layer. As already mentioned above, the work function of the positively biased electrode may have to be lower than that of the negatively biased electrode to ensure a low dark current.

The photoactive layer may consist of a blend of p-type polymer, e.g. P3HT, and n-type molecules, e.g. PCBM, which may be arranged as bulk-heterojunction (BHJ) or a bilayer diode.

On the upper side encapsulation of the OPD is provided by the (sealed) TFT backplane. Below the OPD a glass plate may be beneficial in terms of encapsulation, being easier to apply and more robust than thin-film sealing, which would be needed, if the OPD is placed directly underneath the scintillator.

To ensure a proper and reliable device performance it may be important to establish a good electrical contact between the TFT backplane and the OPD stack structure. It is believed that the best way to achieve this may be to deposit the OPD stack directly on the TFT backplane instead of coupling the OPD and TFT structures after OPD processing on a separate substrate, referred to as indirect deposition.

As mentioned above, to obtain a good quality ITO layer it may be necessary to deposit the ITO layer on the TFT backplane. This restriction may limit the number of possible geometries with ITO to the embodiments depicted in FIGS. 2 and 3. For realization of the geometry depicted in FIGS. 2 and 3 the following manufacturing flows may be used, depending on whether the (0)TFT backplane is based on a foil or glass substrate.

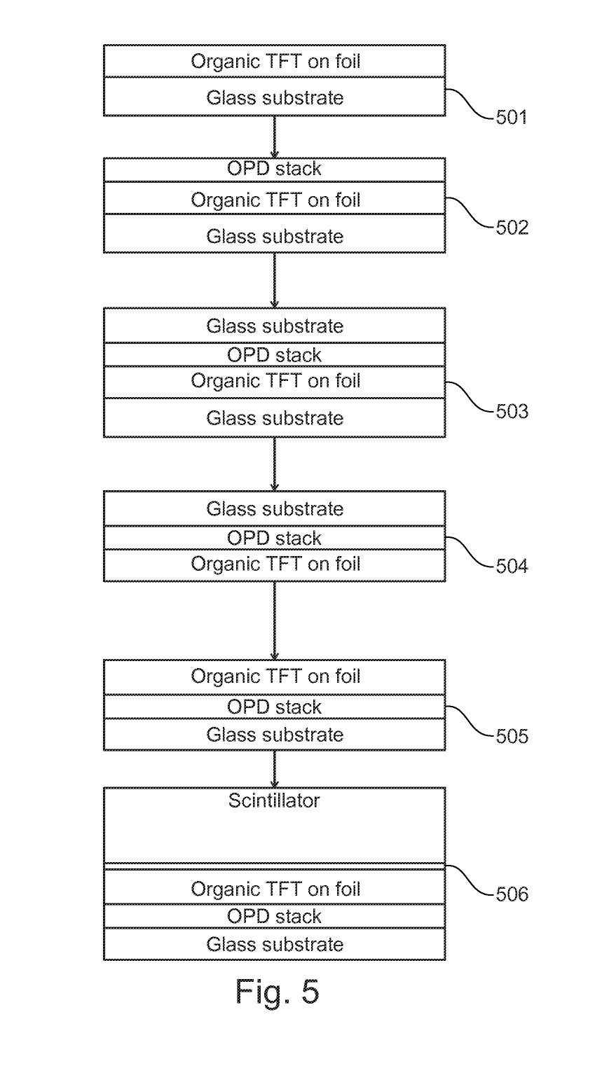

According to the method depicted in FIG. 5, a, for example organic, TFT on foil is attached on a glass substrate (step 501). In step 502 an OPD stack is deposited on the TFT backplane. Then, in step 503, the glass substrate 109 (see FIG. 2) is attached to the OPD stack and in step 504 the other glass substrate or foil on which the TFT backplane has been arranged in the beginning, is detached from the TFT backplane. Then, in step 505 the TFT-OPD stack is flipped and the scintillator is attached to the TFT-OPD stack in step 507, for example by gluing it onto the TFT on foil.

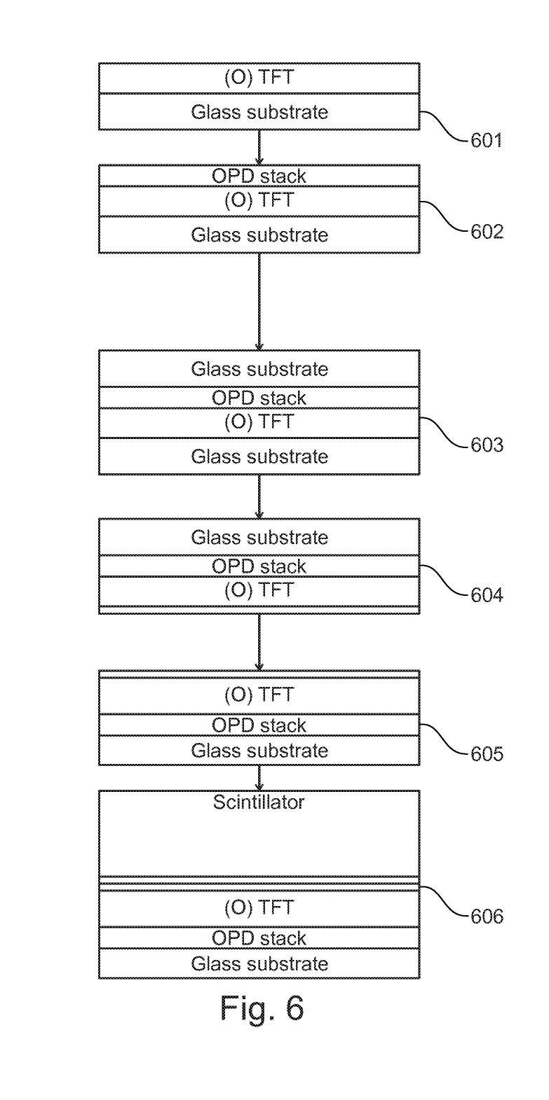

FIG. 6 shows a flow-chart of a method according to another exemplary embodiment of the present invention in which (O)TFT on glass substrate is provided in step 601. Then, in step 602, the OPD stack is deposited on the TFT backplane, after which, in step 603, the glass substrate is attached to the OPD stack. Then, in step 604, the glass substrate on the TFT side (the one from step 601) is thinned to a thickness of 30 μm or less.

Then, in step 605 the TFT-OPD stack is flipped and the scintillator is attached to the TFT-OPD stack in step 606, for example by gluing.

Thinning of the glass substrate in step 604 is for example performed by etching or grinding.

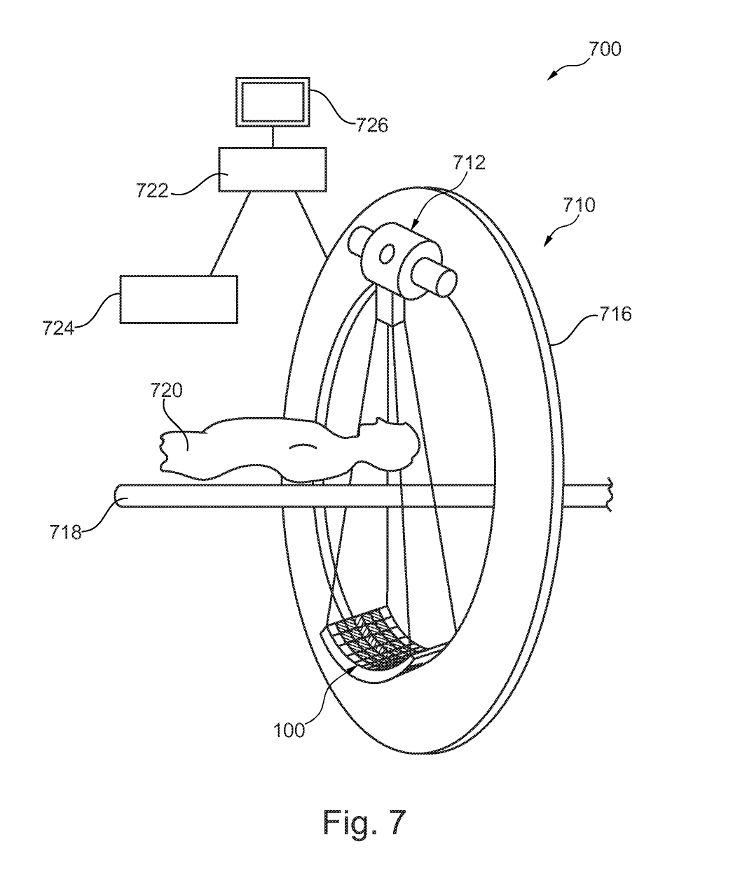

FIG. 7 shows an x-ray imaging system 700, comprising an x-ray source 712 and an x-ray detector 100. For example, the x-ray imaging system 700 is a CT imaging system, comprising a gantry 716, on which the x-ray source 712 and the x-ray detector 100 are mounted opposite to each other, and where they can be rotated on the gantry in a common movement. Further, a patient table 718 is shown, on which an object, for example a patient 720, is arranged. Still further, a processing unit 722, an interface unit 724 and a display unit 726 are provided.

It should be noted that, although FIG. 7 shows a CT imaging system, also other imaging systems are provided by the present invention, for example a C-arm imaging system. In particular, the radiation detectors disclosed by the present invention may be adapted for applications like general radiography, mammography and interventional imaging, such as cardio-vascular interventional imaging. In case of computed tomography detectors, the radiation detector may comprise a plurality of smaller detector modules joined together to a curved detector or may comprise a plurality of flexible components that can be bent to the right curvature.

It has to be noted that embodiments of the invention are described with reference to different subject matters. In particular, some embodiments are described with reference to method type claims whereas other embodiments are described with reference to the device type claims. However, a person skilled in the art will gather from the above and the following description that, unless otherwise notified, in addition to any combination of features belonging to one type of subject matter also any combination between features relating to different subject matters is considered to be disclosed with this application. However, all features can be combined providing synergetic effects that are more than the simple summation of the features.

While the invention has been illustrated and described in detail in the drawings and foregoing description, such illustration and description are to be considered illustrative or exemplary and not restrictive. The invention is not limited to the disclosed embodiments. Other variations to the disclosed embodiments can be understood and effected by those skilled in the art in practicing a claimed invention, from a study of the drawings, the disclosure, and the dependent claims.

In the claims, the word “comprising” does not exclude other elements or steps, and the indefinite article “a” or “an” does not exclude a plurality. The mere fact that certain measures are re-cited in mutually different dependent claims does not indicate that a combination of these measures cannot be used to advantage. Any reference signs in the claims should not be construed as limiting the scope.

1. Radiation detector for an examination apparatus, the radiation detector comprising:
a scintillator for receiving and absorbing incident radiation and for converting the incident radiation into photons;
a thin-film transistor prepared on a substrate, the substrate being arranged between the thin-film transistor and the scintillator;
a photoactive layer arranged at a side of the thin-film transistor facing away from the substrate.

2. Radiation detector of claim 1,
wherein the thin-film transistor and the substrate are optically transparent for allowing photons emitted from the scintillator to pass through the substrate and the thin film transistor and to reach the photoactive layer.

3. Radiation detector of claim 1,
wherein the photoactive layer comprises an organic photo diode.

4. Radiation detector of claim 1,
wherein the thin-film transistor is an organic thin-film transistor.

5. Radiation detector of claim 1,
wherein the substrate is at least one of a foil substrate or a glass substrate.

6. Radiation detector of claim 1, further comprising:
a cathode for the photoactive layer arranged at a side of the photoactive layer facing away from the thin-film transistor;
wherein the cathode comprises an unstructured metal layer which serves as a mirror for photons emitted from the scintillator.

7. Radiation detector of claim 1, further comprising:
a glass substrate arranged at the side of the photoactive layer facing away from the thin-film transistor.

8. Radiation detector of claim 1, adapted as an x-ray detector.

9. Examination apparatus comprising a radiation detector according claim 1.

10. (canceled)

11. Examination apparatus of claim 9, adapted as a medical x-ray imaging system.

12. Method of producing a radiation detector, comprising the following steps:
providing a substrate;
depositing a thin-film transistor layer on a first side of the substrate;
arranging a photodiode stack on the thin-film transistor layer;
attaching a scintillator for receiving and absorbing incident radiation and for converting the incident radiation into photons to a second side of the substrate which is opposite to the first side.

13. Method of claim 12,
wherein the photodiode stack is deposited on the thin-film transistor layer.

14. Method of claim 12, further comprising the step of:
arranging a glass substrate at the side of the photodiode stack facing away from the thin-film transistor layer.
